(19) United States
(12) Patent Application Publication
(10) Pub. No.: US 2014/0244187 A1
(43) Pub. Date: Aug. 28, 2014

(54) Method for Detecting Islanding with Periodically Transmitted Sequence of Unsynchronized Signals

(71) Applicant: MITSUBISHI ELECTRIC RESEARCH LABORATO, Cambridge, MA (US)

(72) Inventors: Zafer Sahinoglu, Cambridge, MA (US); Jianlin Guo, Newton, MA (US); Ziufeng Song, Storrs, CT (US)

(73) Assignee: MITSUBISHI ELECTRIC RESEARCH LABORATORIES, INC., Cambridge, MA (US)

(21) Appl. No.: 13/775,386

(22) Filed: Feb. 25, 2013

(51) Int. Cl. G01R 31/08

(52) U.S. Cl. CPC G01R 31/088
USPC 702/58

(57) ABSTRACT

Conditions in a power grid are detected by sampling a voltage in the grid. A normal condition hypothesis is modeled as a sinusoid, and a transient condition hypothesis is modeled as a sum of damped sinusoids. The samples are used to construct a probability density function. A likelihood ratio based on the pdf and the hypotheses is compared to a threshold to determine whether the condition is normal or transient.

### FIELD OF THE INVENTION

This invention relates generally to detecting abnormal conditions in electric power systems, and in particular to detecting islanding.

### BACKGROUND OF THE INVENTION

Islanding in Power System

Distributed generators are becoming an important component in electric power systems. Distributed generators are small, can be used with renewable energy, such as solar energy; wind energy and hydraulic energy. Therefore, distributed generators provide numerous benefits to electric power system, such as solving local power shortage problems.

However, when the distributed generators are operated in conventional power systems, islanding can occur. Islanding is an abnormal condition in which one or more distributed generators continue to power a portion of the system, even primary power from a grid is no longer present.

There are two types of islanding: intentional islanding and unintentional, intentional islanding is a scheduled islanding. During intentional islanding, the distributed generators are coordinated and controlled by an operator of the system. Intentional islanding is safe. Unintentional islanding is an unplanned abnormal condition, which can harm the system, connected equipment and people. Therefore, unintentional islanding must be detected in a very short time so that all distributed generators are shirt down, or disconnected from grid immediately. For example, the IEEE 1547 Standard for Interconnecting Distributed Resources with Electric Power Systems requires a detection time of less than two seconds. Section 4.4.1 of the IEEE 1547 standard states: “For an unintentional island in which the DR energizes a portion of the Area EPS (electric power system) through the FCC (points of common coupling), the DR (distributed resource) interconnection system shall detect the island and cease to energize the Area EPS within two seconds of the formation of an island.”

A number of islanding detection methods are known, including active detection, and passive detection. Activate methods bias the voltage, frequency, current or phase of a distributed generator connected to a power grid. The impact of the biasing on the system operating parameters can then be measure to determine whether islanding exists. Passive methods rely on the detection of an abnormality in the voltage, frequency, current or phase. If these parameters are above or below the normal operating values, then, an islanding can occur. A common drawback of conventional islanding detection methods is the existence of a non-detection zone. In other words, there is not a reliable way to detect islanding.

For reliable islanding detection, communication based methods are known. Those methods involve transmitting signal from the grid to distributed generator to determine when to stop or continue operation.

For example, U.S. Pat. No. 7,225,087 describes a method and apparatus for detecting unintentional islanding in a utility grid. The method generates a user defined control signal, and applies the control signal to a distributed resource interconnected to the utility grid.

U.S. Pat. No. 7,376,491 describes a method for defecting islanding in a power grid having a power line voltage. The method monitors a detectable signal different from the power line voltage at a generating station, and superimposes the detectable signal onto the power line voltage at a grid point outside the generating station. The generating station is switched from a grid-connected mode of operation to an islanded mode of operation when the signal is absent.

U.S. Pat. No. 7,138,728 describes anti-islanding techniques for distributed power generation. That method includes a current pulse in the output of a distributed power source. The grid voltage is monitored at a node to determine when a pulse-related disturbance occurs. If the grid is present, then no-pulse-related disturbances occur. Detection of the pulse-related disturbance is used to signal the islanding.

### SUMMARY OF THE INVENTION

The embodiments of the invention provide a method for detecting islanding in an electric power system. A signal generator periodically generates a signal sequence for a local electric power system. An islanding detector samples the power signal at a distributed generator. A binary hypothesis test and a likelihood ratio test (LRT) are used to detect the islanding. The signal generator and the distributed generators can be unsynchronized for cost and operational efficiency.

The method does not need the fundamental frequency, initial phase, or amplitude of the voltage. Therefore, the performance of the method is preserved under non-ideal situations, such as frequency deviation from the nominal frequency of the power grid.

The samples can be compared with a normal probability distribution function (pdf) and an islanding pdf to detect the islanding because the pdfs have different means and covariances.

A likelihood ratio test determines whether the signal samples correspond to a normal hypothesis (H₀), or the islanding hypothesis (H₁).

In one embodiment, the islanding detection is formulated as a parameter test, which is solved using a likelihood ratio test (LRT). In this embodiment, the LRT is a statistical test to compare the fit of two models, one of which is a model for the normal condition, and the other a model for the islanding. The test is based on the likelihood ratio of the models.

For example, if the LRT ratio is not equal to one, then the islanding is detected. In one variation of this embodiment, the islanding is detected if a difference between one and the LRT ratio is greater than a threshold.

The invented islanding detection method can be applied to electric power system with multiple distributed generators, in single-phase and three-phase electric power system, as well as other distributed generators.

### BRIEF DESCRIPTION OF THE DRAWINGS

FIG. 1 is schematic of electric power system in which the invented islanding detection method operates;

FIG. 2 is a block diagram of the method for detecting islanding in an electric power system and controlling operation of distributed generator according to an embodiment of an invention;

FIG. 3 is a block diagram of the stochastic islanding detector and process according to embodiments of the invention;

FIG. 4 a block diagram of a signal sequence used by embodiments of the invention; and

FIG. 5 is a graph of a performance of the islanding detection, method according to an embodiment of an invention.

### DETAILED DESCRIPTION OF THE EMBODIMENTS

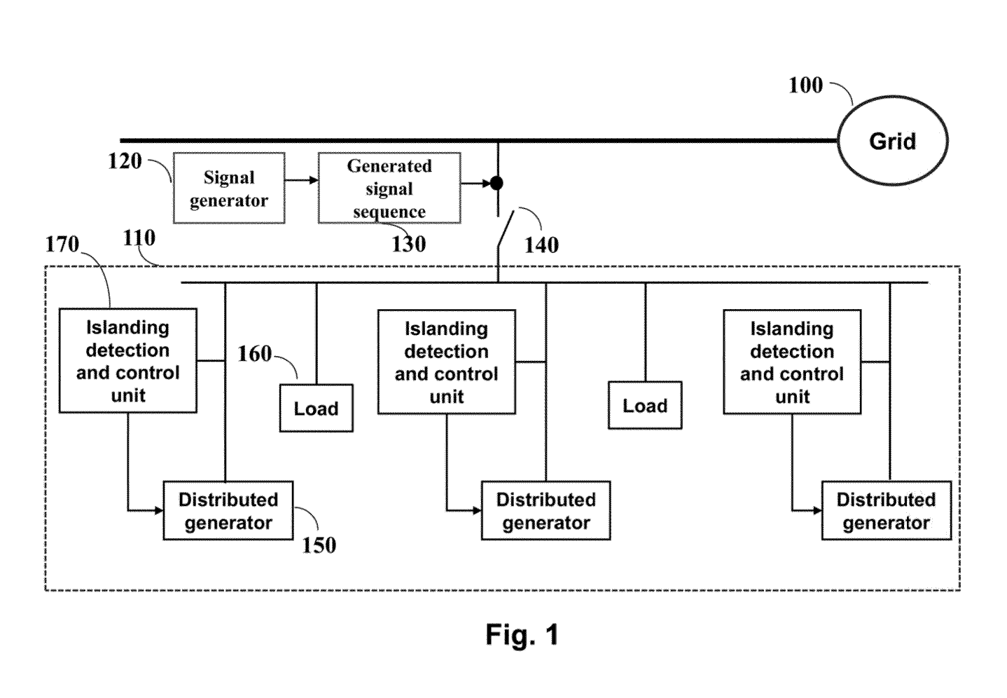

FIG. 1 shows a schematic of electric power system in which our islanding detection method can operate. A grid power source 100 provides primary power to an electric power system. There are multiple distributed generators 150, such as a solar panel, a wind turbine, a tidal generator, a wave generator, or a backup generator, connected to the electric power system as secondary power sources.

Typically, there are also multiple loads 160 connected to the electric power system. Distributed generators and loads form a local electric power system 110. A signal generator 120 is installed in the distribution network outside of breaker switch 140 to generate a signal sequence 130 for the local electric power system. At each distributed generator, an islanding detection and control unit 170 is installed to detect islanding and control operation of the distributed generators. The signal generator and the islanding detection and control unit are unsynchronized to reduce the cost and maintenance, because synchronization is complex, particularly with, a frequently regulated power flow.

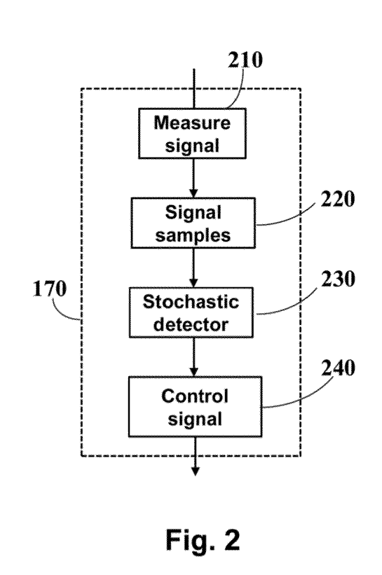

FIG. 2 shows block diagram of islanding detection and control unit 170. The method measures 210 a signal from power line to obtain samples 220. The samples are input for a stochastic detector 230. Based on a signal processing result, the stochastic detector generates control signal 240 to the distributed generator 150. If islanding is detected, then the distributed generator can either shutdown or operates in an islanding mode. If operating in the islanding mode, then the distributed generator must follow configurations of the islanding mode.

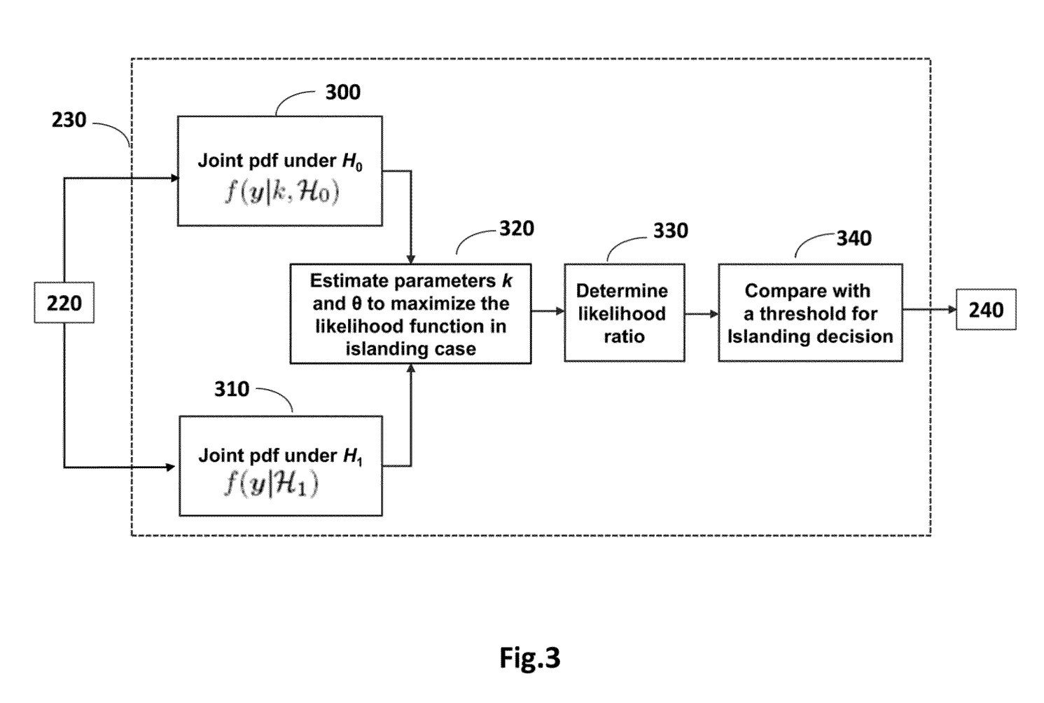

FIG. 3 shows block diagram of stochastic detector. The islanding detection problem is modeled as a binary hypothesis test. The detection with known and unknown sequences energy are derived, respectively.

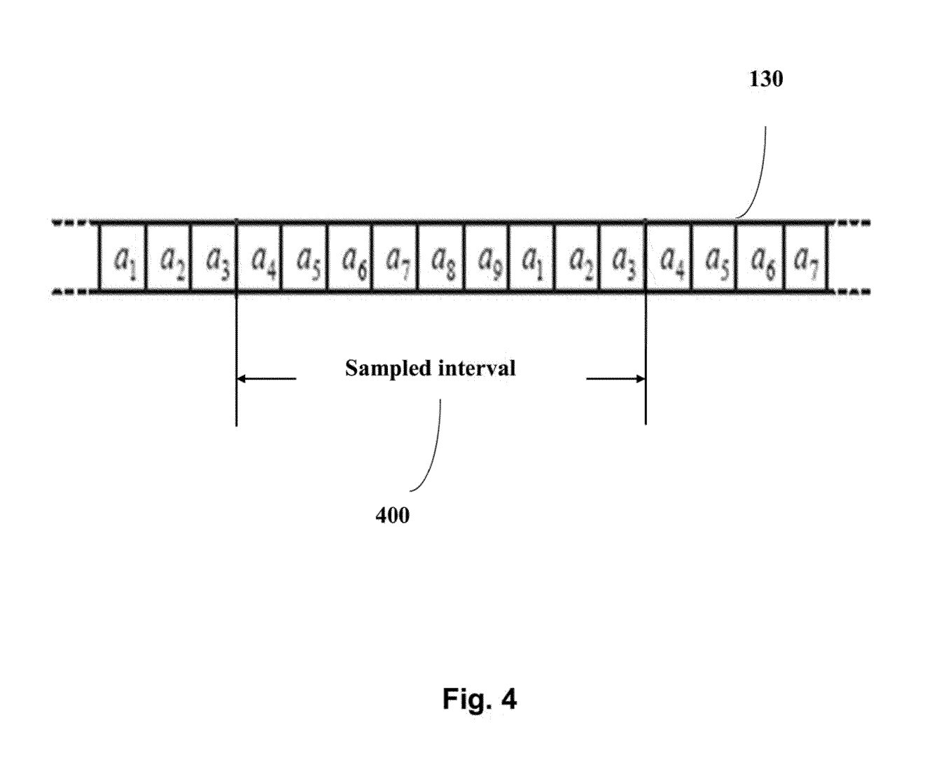

Signal generator 120 periodically generates a signal sequence a=[a₁, a₂, . . . , aₙ]^{T} for the power line, see FIG. 4, where T is a transpose operator.

FIG. 4 shows an example sequence 310, and a sampling interval 400 of nine samples.

The islanding detection and control unit 170 at the distributed generator samples the power line signal to determine whether the local power system 110 is islanded. Suppose the fundamental frequency component has been removed, if the local power system is connected to the grid, then the transmitted signal sequence can flow to the islanding detection and control unit. Therefore, the extracted signal samples can be expressed as

y=θP^{k}a+w (1)

where w˜N(0,σ²Iₙ) denotes the zero-mean white Gaussian receiver noise, and Iₙ is a n×n identity matrix; θ>0 can be either known or unknown, and θ² represents the power of the sequence, P is the unit time shift matrix

$$P = [ \begin{matrix} & 1 \\ {I}_{n - 1} & \end{matrix} ] \qquad ( 2 )$$

and 0 [symbol] k [symbol] n−1 is an unknown integer, and indicates where the samples starts.

If islanding occurs, then the samples form a noise vector

y=w (3)

Hence, the islanding detection problem is recast as a binary hypothesis test

H₀:y=θP^{k}a+w vs, H₁:y=w (4)

where the hypothesis H₀ denotes the normal condition, and H₁ indicates islanding.

Stochastic Detection with θ Known

If θ is known, islanding detection problem can be solved via the likelihood ratio test (LRT)

$$\frac{{max}_{k} f ( y \vert k , {ℋ}_{0} )}{f ( y \vert {ℋ}_{1} )} {{≷}_{{ℋ}_{1}}}^{{ℋ}_{0}} T , \qquad ( 5 )$$

where T denotes the threshold, ƒ(y|k, H₀) 300 and ƒ(y|H₁) 310 are likelihood functions. Since

$$f ( y \vert k , {ℋ}_{0} ) = \frac{1}{\sqrt{{( 2 π )}^{n} {σ}^{2 n}}} {e}^{- \frac{1}{2 {σ}^{2}} {‖ y - θ {P}^{k} a ‖}^{2}} \\ f ( y \vert {ℋ}_{1} ) = \frac{1}{\sqrt{{( 2 π )}^{n} {σ}^{2 n}}} {e}^{- \frac{1}{2 {σ}^{2}} {‖ y ‖}^{2}} , \qquad ( 6 )$$

the likelihood ratio test in equation (5) can be simplified as

$${max}_{k} {y}^{T} {P}^{k} a {{≷}_{{ℋ}_{1}}}^{{ℋ}_{0}} T , \qquad ( 7 )$$

where the threshold T has been properly transformed. The threshold can be based on a desired probability of a false alarm. The optimal detector expressed by equation (7) selects 320 the most likely start point k in the decision making. With both k and θ determined, the likelihood functions ƒ(y|k, H₀) 300 and ƒ(y|H₁) 310 are used to determine 330 the likelihood ratio, which is used to compare 340 with a transformed threshold T to determine islanding and generates 240 control signal to the distributed generator, e.g., to disconnect or turn the generator off,

Stochastic Detection with θ Unknown

If θ is unknown, the binary hypothesis test contains two unknown parameters: θ and k. The detection can be solved via a generalized LRT

$$\frac{{max}_{k , θ} f ( y \vert k , {ℋ}_{0} )}{f ( y \vert {ℋ}_{1} )} {{≷}_{{ℋ}_{1}}}^{{ℋ}_{0}} T , \qquad ( 9 )$$

or, equivalently,

$${max}_{k} {max}_{θ} [ 2 θ {y}^{T} {P}^{k} a - {θ}^{2} ] {{≷}_{{ℋ}_{1}}}^{{ℋ}_{0}} T . \qquad ( 10 )$$

where the threshold T has also been properly transformed. The optimal detector according to equation (10) selects 320 the most likely start point k and θ in the decision making. With both k and θ determined, likelihood functions ƒ(y|k, H₀) 300 and ƒ(y|H₁) 310 are used to determine 330 the likelihood ratio, which is used to compare 340 with a transformed threshold T to determine islanding and generates 240 control signal to the distributed generator.

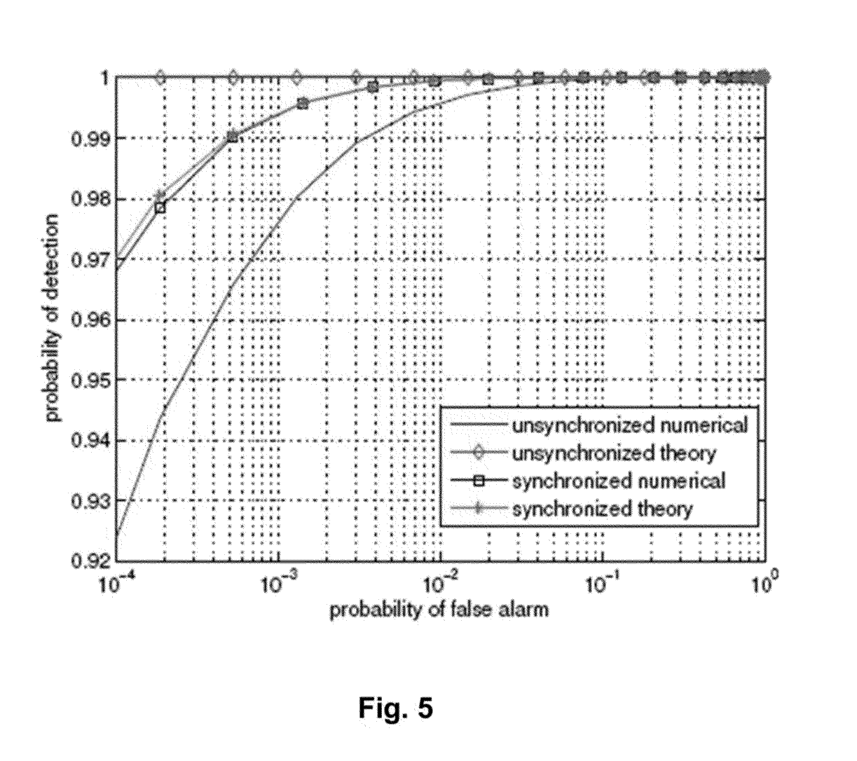

FIG. 5 shows the performance of the detection method as a function of probability of detection vs. false alarm for theoretical and numerical results with synchronized and unsynchronized signals. For example, the probability of detection of 0.95 is achieved at a SNR of 12 dB, and probability of false alarm of 0.02.

Distributed generators are expected to be an important component in electric power system. However, besides providing extra, power to electric power system, the distributed generators can also cause unintentional islanding in electric power system. Unintentional islanding must be reliably detected and operation of distributed generators must be controlled based on islanding detection decision.

The invention provides a method for detecting the islanding using a binary hypothesis test. A signal generators transmits a sequence of signals into power line periodically. An islanding detector measures transmitted signal samples and uses measured samples to determine islanding condition. A normal condition is modeled as hypothesis (H₀) and the islanding is modeled as hypothesis (H₁).

Because the parameters of the models are unknown, a likelihood ratio test is used on probability distribution functions constructed from measured samples of the power line. The likelihood ratio of the pdfs is compared to a threshold to determine if the condition of the network is normal or islanding.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. A method for detecting islanding in electric power system, comprising the steps of:
generating a sequence signal for a power line in the electric power system;
measuring samples of the power signal including the signal sequence at a distributed generator;
modeling a normal condition hypothesis, and an islanding hypothesis;
constructing a probability density function (pdf) from the samples; and
comparing a likelihood ratio based on the pdf and the hypotheses to a threshold to determine the islanding, wherein the steps are performed in a processor.

2. The method of claim 1, wherein the signal sequence is generated by a signal generator, and a measurement device measures the samples.

3. The method of claim 1, wherein the power signal is 1-phase or 3-phase.

4. The method of claim 1, wherein the distributed generator is selected from a group consisting of a solar panel, a wind turbine, a tidal generator, a wave generator, and a backup generator.

5. The method of claim 1, wherein the signal generator and measurement device are unsynchronized.

6. The method of claim 1, wherein the samples are analyzed for a best fit to the pdf in a stochastic detector.

7. The method of claim 1, wherein the samples include normal samples and islanding samples, and a normal hypothesis is
H₀:y=θP^{k}a+w,
and an islanding hypothesis is
H₁:y=w.

8. The method of claim 7, further comprising:
estimating k and θ using a likelihood ratio test.

9. The method of claim 1, wherein the comparing further comprises:
determining a likelihood ratio of a normal pdf and an islanding pdf; and
thresholding the likelihood ratio.

10. The method of claim 9, wherein the thresholding is based on a desired probability of a false alarm.
